(19) United States
(12) Patent Application Publication
(10) Pub. No.: US 2009/0186148 A1
(43) Pub. Date: Jul. 23, 2009

(54) Method of fabricating organic light emitting device

(76) Inventors: Yu-Jin Kim, Yongin-si (KR); Jun-hee Choi, Yongin-si (KR); Andrei Zoulkarneev, Yongin-si (KR); Tae-yong Noh, Yongin-si (KR); Byoung-ki Choi, Yongin-si (KR); Myeong-suk Kim, Yongin-si (KR); Dong-woo Shin, Yongin-si (KR); Tae-woo Lee, Yongin-si (KR); Yu-ri Choi, Yongin-si (KR)

Correspondence Address: ROBERT E. BUSHNELL & LAW FIRM, 2029 K STREET NW, SUITE 600, WASHINGTON, DC, 20006-1004, US

(21) Appl. No.: 12/219,219

(22) Filed: Jul. 17, 2008

(30) Foreign Application Priority Data
Jan. 22, 2008 (KR) 10-2008-0006701

(51) Int. Cl. B05D 5/12

(52) U.S. Cl. 427/66

(57) ABSTRACT

In a method of forming a pattern of an organic light emitting device (OLED), an organic material is evaporated in a predetermined pattern by using a pre-patterned heating element, and the evaporated organic material is transferred to a substrate where the OLED is formed. The method includes preparing a template having a heating element in a pattern corresponding to a multilayered structure of an OLED including a plurality of functional layers; forming an organic layer on the heating element; drawing a substrate for the OLED near to the heating element of the template; and transferring the organic layer on the heating element to the substrate by evaporating the organic layer using the heating element.

### PRIORITY STATEMENTS

This application makes reference to, incorporates the same herein, and claims all benefits accruing under 35 U.S.C. §119 from an application for METHOD OF FABRICATING ORGANIC LIGHT EMITTING DEVICE earlier filed in the Korean Intellectual Property Office on 22 Jan. 2008 and there duly assigned Serial No. 10-2008-0006701.

### BACKGROUND

1. Field

Example embodiments relate to a method of transferring microstructure by using a micro-heating array, and more particularly, to a method of forming a pattern or an image of an organic electroluminescent component.

2. Description of the Related Art

Generally, organic light emitting devices (OLEDs) are devices that emit light by recombination of holes supplied from an anode and electrons supplied from a cathode in an organic light emitting layer formed between the anode and the cathode. The OLEDs are regarded as a next generation technology that may be widely applied to televisions (TVs), personal computers (PCs) monitors, mobile communication terminals, MP3 players, and navigators for automobiles due to the OLEDs' advantages of the higher color reproducibility, the faster response speed, the spontaneous emission, the thinner thickness, the higher contrast ratio, the wider viewing angle, and the lower power consumption. Meanwhile, because of the characteristic of the spontaneous emission, OLEDs may also be used in internal and external illuminations or signs that may require to adjust colors. Also, OLEDs are environmental friendly devices that can reduce the amount of carbon dioxide emissions compared to conventional illuminations.

Various methods of forming a light emitting structure have been applied to a method of fabricating the OLED. Examples of methods of forming a light emitting structure include an evaporation method using a shadow mask, a printing method using an ink jet, and a local thermal transfer method using a laser. An evaporation pattern is determined by a shadow mask in the evaporation method, a desired pattern is formed by supplying a plated material only on a predetermined area in the printing method, and a desired pattern is obtained by heating a middle object in the desired pattern by using a laser in the local thermal transfer method.

The contemporary methods of fabricating OLEDs generally require a separate patterning device or process, a donor film, and organic patterning masks such as metal shadow masks. Therefore, the contemporary methods are complicated and expensive. Additionally, the substrate, where the pixels are formed, is normally directly heated during forming an organic material, therefore, the material forming the substrate is limited.

### SUMMARY

Example of embodiments relate to a method of fabricating an organic light emitting device (OLED).

Other example of embodiments relate to a method of fabricating an organic light emitting device (OLED), and a micro-pattern maybe easily obtained by this method.

According to examples of embodiments, there is provided a method of fabricating an organic light emitting device (OLED), the method including preparing a template having a heating element in a pattern corresponding to a multilayered structure of an OLED including a plurality of functional layers; forming an organic layer on the heating element; drawing a substrate for the OLED near to the heating element of the template; and transferring the organic layer from the heating element to the substrate by evaporating the organic layer using the heating element.

The formation of the organic layer and transfer of the organic layer may be repeatedly performed so as to form a multilayered structure having different organic layers on the substrate.

The organic layer may be transferred to the substrate while the substrate and the organic layer on the heating element contact each other. The organic layer may be transferred to the substrate while the substrate and the organic layer on the heating element are spaced apart from each other.

The formation of the organic layer and transfer of the organic layer may be repeatedly performed so as to form a multilayered structure of a plurality of OLEDs, and the method may further include a step of forming an organic layer on a substrate of an OLED and forming an organic layer on a substrate of an adjacent OLED so as to simultaneously fabricate the plurality of OLEDs.

The formation of the organic layer and the transfer of the organic layer may be repeatedly performed so as to form a multilayered structure of a plurality of OLEDs, and a multilayered structure of an OLED may be completed before a multilayered structure of an adjacent OLED is formed.

The organic layer may be one of plural materials forming the functional layer of the OLED, and one functional layer may be formed by sequentially stacking each of the plural materials through above mentioned operations.

The preparation of the template may prepare templates each corresponding to a plurality of OLEDs on the substrate. The heating element may be formed correspondingly to a plurality of OLEDs, and is spaced apart from the template.

A supporter, which locally supports the heating element, may be prepared at the bottom of the heating element. A plurality of the supporters may be prepared at the bottom of the heating element, and the supporters are spaced apart from each other.

The functional layer may include an emission layer, an electron transport layer for supplying an electric charge to the emission layer, an electron injection layer, a hole transport layer, and a hole injection layer.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A through 1C are diagrams illustrating procedural steps of transferring an organic layer during fabricating an organic light emitting device (OLED) according to example of embodiments;

FIGS. 2A through 2E are diagrams illustrating procedural steps of transferring an organic layer during fabricating an OLED according to another example of embodiments;

FIGS. 3A through 3H are diagrams illustrating procedural steps of transferring an organic layer during fabricating an OLED according to another example of embodiments;

FIGS. 4A through 4C are diagrams illustrating a structure of a template employed during fabricating an OLED according to example of embodiments; and

FIG. 5 is a photo showing a plan view of a structure of an actual template employed during fabricating an OLED according to examples of embodiments.

### DETAILED DESCRIPTION OF THE INVENTION

Various example of embodiments will be described more fully hereinafter with reference to the accompanying drawings, in which example of embodiments are shown. This should not be construed as limiting the claims to the example of embodiments shown. Rather, these embodiments are provided to convey the scope of the invention to those skilled in the art. In the drawings, the size and relative sizes of elements and regions may be exaggerated for clarity.

It will be understood that when an element or layer is referred to as being “on”, “disposed on”, “disposed”, or “between” another element or layer, it may be directly on, disposed on, disposed, or between the other element or layer, or intervening elements or layers can be present.

The terms “first,” “second,” and the like, “primary,” “secondary,” and the like, as used herein do not denote any order, quantity, or importance, however, rather are used to distinguish one element, region, component, layer, or section from another. The terms “front”, “back”, “bottom”, and/or “top” are used herein, unless otherwise noted, merely for convenience of description, and are not limited to any one position or spatial orientation.

The terms “a” and “an” do not denote a limitation of quantity, however, rather denote the presence of at least one of the referenced item. The suffix “(s)” as used herein is intended to include both the singular and the plural of the term that it modifies, thereby comprising one or more of that term (e.g., the layer(s) includes one or more layers).

Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various exemplary embodiments.

The endpoints of all ranges directed to the same component or property are inclusive of the endpoint and independently combinable, e.g., ranges of “up to about 25 wt. %, or, more specifically, about 5 wt. % to about 20 wt. %,” is inclusive of the endpoints and all intermediate values of the ranges of “about 5 wt. % to about 25 wt. %,” etc. The modifier “about” used in connection with a quantity is inclusive of the stated value and has the meaning dictated by the context (e.g., includes the degree of error associated with measurement of the particular quantity).

Unless defined otherwise, technical and scientific terms used herein have the same meaning as is commonly understood by one of skill in the art to which this invention belongs.

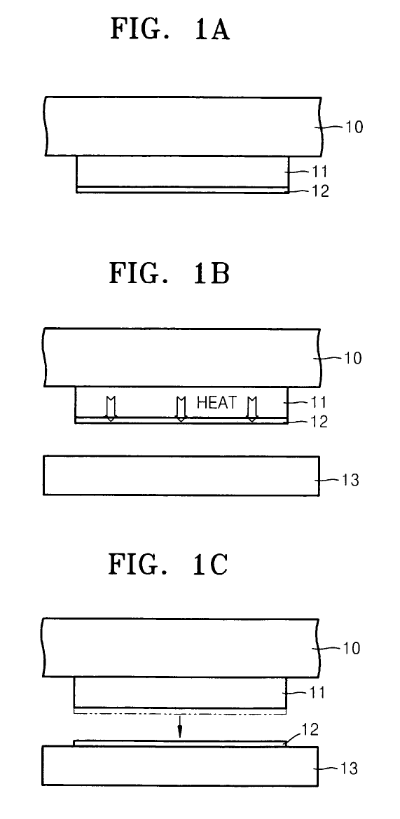

FIGS. 1A through 1C are diagrams for describing a basic concept of a method of fabricating an organic light emitting device (OLED) according to an example of embodiment.

As illustrated in FIG. 1A, an organic layer 12 is formed on one side of a heating element 11, which is formed in a predetermined pattern on a heater, i.e. a template substrate 10 (hereinafter, referred to as a template 10). Here, the predetermined pattern of heating element 11 corresponds to a plan pattern of an OLED. For easy understanding, heating element 11 in FIGS. 1A through 1C is simply illustrated.

As illustrated in FIG. 1B, heating element 11 is heated while organic layer 12 formed on heating element 11 is drawn near to a target substrate 13 (hereinafter, referred to as a substrate 13). substrate 13 may be a substrate where the OLED is formed.

As illustrated in FIG. 1C, organic layer 12 that was deposited on heating element 11 is evaporated so as to transfer organic layer 12 to substrate 13 that is drawn close to heating element 11. The form of transferred organic layer 12 corresponds to a pattern of a multilayered structure of the OLED.

The above processes, i.e., the processes of formation of organic layer 12 on heating element 11 and the transfer of organic layer 12 to substrate 13, may be repeatedly performed while differentiating a type of organic materials so as to form a multilayered structure according to a plurality of organic layers 12.

Referring to FIGS. 1A through 1C, substrate 13 is drawn close to heating element 11, while an evaporation gap of the organic material may exist between organic layer 12, which is a plated material on heating element 11, and substrate 13. According to another embodiment of the present invention, substrate 13 is drawn closer to heating element 11 so that substrate 13 slightly contacts organic layer 12 on heating element 11.

Heating element 11 may have an array formed correspondingly to the arrangement of pixels of the OLED, i.e., a micro-heating array. The pixel includes a driving circuit, which includes a light emitter by an organic light emitting diode, and a plurality of transistors driving the light emitter. As described above, the method forms an organic film on substrate 13 of the OLED by using heating element 11 in a predetermined form, i.e., pre-patterned heating element 11, and thus a separate patterning device or process is not required like contemporary methods of fabricating OLEDs. A micro-heating element arrangement disposed correspondingly to the plurality of pixels, i.e., the micro-heating array evaporates and transfers the organic material to substrate 13 via self-heat emission, or infrared (IR) ray or visible ray emitted from the self-heat emission. The OLED may be formed of a PLED or SMOLED organic material. According to the method, a donor film is not required like a contemporary thermal transfer method, and pixels may be formed in high resolution without an organic patterning mask like a metal shadow mask. By suitably designing a heating array, a screen of the OLED may be easily enlarged. Also, since substrate 13, where the pixels are formed, is not directly heated while forming an organic material, substrate 13 may be a glass substrate or a plastic substrate.

The method according to the current example of embodiment includes forming a heating element having a pattern corresponding to a multilayered structure of an OLED or a micro-heating array on a template; forming an organic layer on the heating element of the template; drawing a substrate for forming the OLED close to the heating element of the template; and transferring the organic layer formed on the heating element to the substrate by evaporating the organic layer by generating heat from the heating element.

According to another example of embodiment, the organic layer transferred to the substrate is formed of one of plural materials forming any one of a functional layer of the OLED.

According to another example of embodiment, a plurality of templates having heating elements in different patterns may be formed during the forming of the template, and organic layers having different patterns are transferred to the substrate by using the templates.

Also, each functional layer, for example, an emission layer, an electron transport layer, an electron injection layer, a hole transport layer, or a hole injection layer, includes at least one organic material. Several organic materials forming each functional layer are separately transferred without being mixed so as to form a separate layer on the substrate, and then are mixed to one material on the substrate.

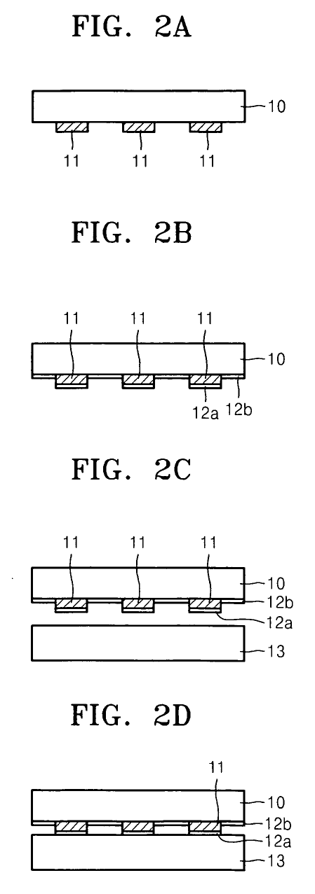

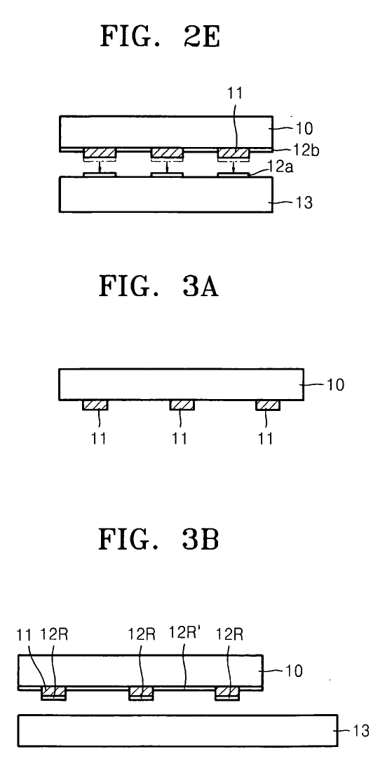

FIGS. 2A through 2E are diagrams for describing a method of forming an organic multilayered structure according to an embodiment of the present invention by using a plurality of heating elements 11 disposed in an array.

As illustrated in FIG. 2A, the plurality of heating elements 11 are formed in a predetermined interval on a template 10. The size and the interval of heating elements 11 correspond to each pixel of an OLED. The width of heating elements 11 is equal to the width of the OLED, and the pitch of heating elements 11 is equal to the pitch of the pixels.

As illustrated in FIG. 2B, a predetermined organic material is deposited on template 10 so as to form an organic layer 12a on heating element 11. Here, an organic layer 12b is also formed on the surface of template 10.

As illustrated in FIG. 2C, a substrate 13 is drawn close to heating elements 11. Here, organic layer 12a and substrate 13 may maintain a narrow gap as shown in FIG. 2C, or contact each other as shown in FIG. 2D.

As illustrated in FIG. 2E, organic layer 12a on the surface of heating element 11 is transferred to substrate 13 by evaporating organic layer 12a using heating elements 11. Like FIG. 2C, the transferring of organic layer 12a is completed while organic layer 12a and substrate 13 are spaced apart from each other.

Processes in FIGS. 2B through 2E are processes for forming a functional layer or a unit lamination for a functional layer, and may be repeated so as to form an OLED having a plurality of functional layers.

Organic layer 12a, that is transferred to substrate 13 by heating element 11 in a micro-size disposed in an array, i.e., a micro-heating array, may include a functional layer of an OLED stacked vertically onto substrate 13, such as a hole injection layer, a hole transport layer, an emission layer, an electron transport layer, an electron injection layer, a hole block layer, or an electron block layer. Such functional layers form one stacked layer via a transfer method described above, and thus a desired OLED may be obtained.

Organic layer 12a formed on heating element 11 may be formed by well-known deposition methods, such as a sputtering method, an e-beam deposition method, and a thermal deposition method. Heating element 11 emits heat when a voltage is applied, and conducted heat and radiant heat from heating element 11 are absorbed by organic layer 12a formed on heating element 11.

Accordingly, organic layer 12a is vaporized and then transferred to substrate 13. Here, substrate 13 is not directly heated, but only organic layer 12a formed on heating element 11 is heated. Substrate 13 may be formed of glass or plastic, and thus the method of the present invention may be applied to SOC (system on glass) or SOP (system on plastic). By using the processes as stated above, an OLED may be quickly and economically fabricated compared to the contemporary fabricating method.

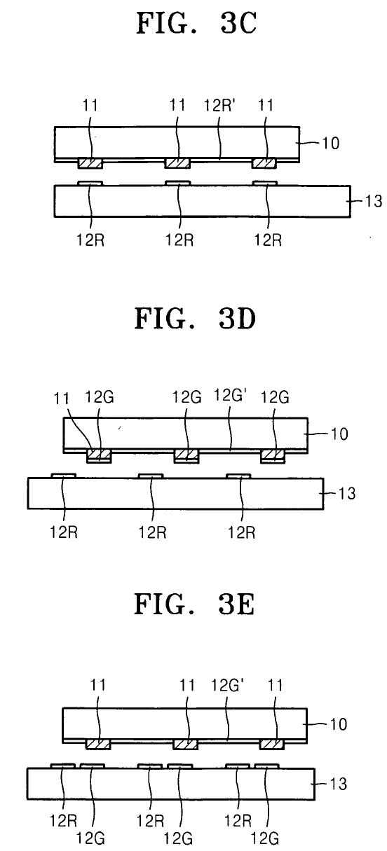

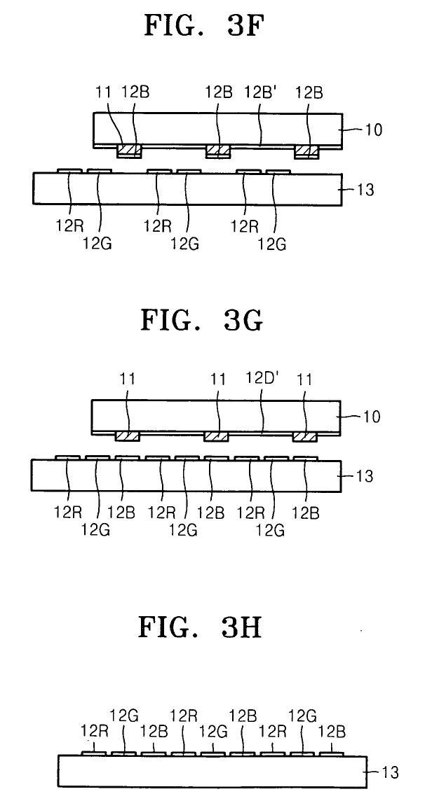

Red (R), green (G), and blue (B) OLEDs for color display may be formed by coating different organic layers in a continuous area. While fabricating each color OLED on one substrate, the R, G, and B OLEDs may be separately formed, or simultaneously formed. FIGS. 3A through 3H are diagrams for describing a method of simultaneously forming R, G, and B OLEDs on a substrate 13, where a unit organic layer of each OLED is sequentially formed.

As illustrated in FIG. 3A, heating elements 11, which are arranged correspondingly to an arrangement of the R, G, and B OLEDs, are formed on one side of a template 10. The pitch of heating elements 11 corresponds to the pitch of a pixel of the same displayed color.

As illustrated in FIG. 3B, organic layers 12R and 12R′ are formed on template 10, and then substrate 13 is drawn close to template 10. Here, organic layer 12R corresponds to, for example, a functional layer of the R OLED.

As illustrated in FIG. 3C, heating elements 11 are heated so as to vaporize organic layers 12R to be transferred from the surface of the heating elements 11 to substrate 13. Areas on substrate 13 where organic layers 12R are transferred are areas that are defined as red emission areas.

As illustrated in FIG. 3E, after depositing organic layers 12G, which are to be used as functional layers of G OLED, on template 10 having heating elements 11, substrate 13 is drawn close to template 10. Here, heating elements 11 are located to face and are opposite to defined green emission areas so that heating elements 11 do not overlap areas of organic layers 12R previously formed.

As illustrated in FIG. 3E, heating elements 11 are heated so as to transfer organic layers 12G on the surface of heating elements 11 to the green emission areas of substrate 13.

As illustrated in FIG. 3F, after depositing other organic layers 12B, which are to be used as functional layers of B OLED, on template 10 having heating elements 11, substrate 13 is drawn close to the template. Here, heating elements 11 are located to face and are opposite to defined blue emission areas so that heating elements 11 do not overlap areas of organic layers 12R and 12G previously formed.

As illustrated in FIG. 3G, organic layers 12B are evaporated by using heating element 11 so as to be transferred to the blue emission areas of substrate 13.

FIG. 3H shows the arrangements of organic layers 12R, 12G, and 12B formed on substrate 13 obtained through the procedural steps as shown in FIGS. 3A through 3G. After obtaining organic layers 12R, 12G, and 12B, other organic layers of corresponding color OLEDs may be individually transferred to organic layers 12R, 12G, and 12B. Here, above stated steps may be repeated.

In the above processes, organic layers of each pixel are accumulated together in each step, however, it is possible to form an OLED of one color area and then form an OLED of another color area. In other words, the processes illustrated in FIGS. 2A through 2D may be repeatedly performed by changing an organic layer so as to form one OLED, and then form another OLED after changing designated transfer locations.

In FIGS. 3A through 3H, it has been described that organic layers 12R, 12B, and 12G on heating elements 11 maintain a uniform gap with substrate 13, without contacting substrate 13. According to another embodiment of the present invention, however, organic layers 12R, 12B, and 12G may physically contact substrate 13.

Meanwhile, heating elements 11 contact template 10 in the drawings related to the exemplary embodiments described above. In this case, heat generated by heating elements 11 is absorbed by template 10, and thus in order to evaporate organic layers 12R, 12B, and 12G, heating elements 11 should be heated considering heat loss induced by template 10. In order to suppress the heat loss of heating elements 11 by heat absorption of template 10, heating elements 11 may be spaced apart from template 10.

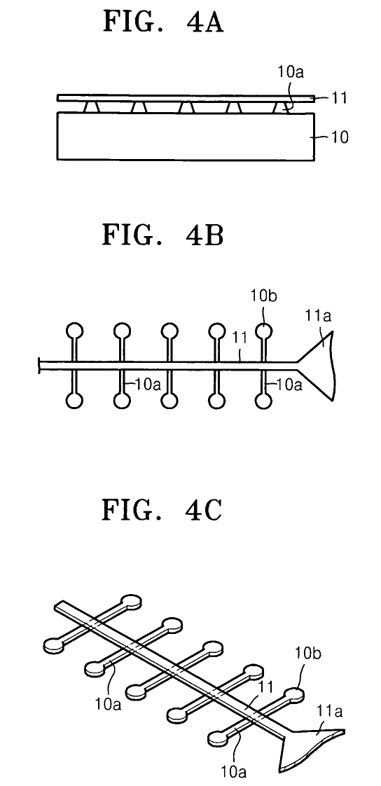

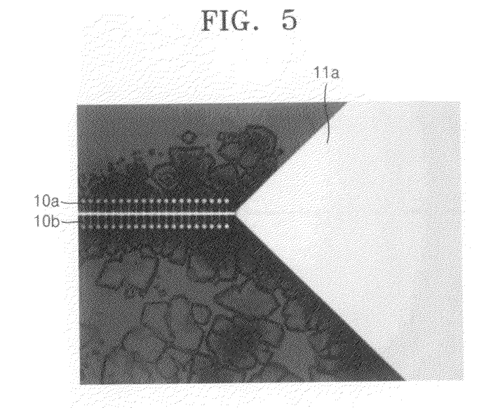

FIG. 4A is a cross-sectional view of the arrangement of heating element 11 spaced apart from a template 10, FIG. 4B is a plan view illustrating heating element 11 and supporters 10a therefor, FIG. 4C is a perspective view of FIG. 4B, and FIG. 5 is a partial excerpted photo of an actual template 10.

Supports 10a are formed in a predetermined interval on template 10, and heating element 11 are formed on supporters 10a. In other words, heating elements 10 are suspended in a predetermined height from the surface of template 10 by supporters 10a. Electrodes 11a are formed on both ends of heating element 11 (in FIGS. 4A through 4C, only one electrode 11a is illustrated in one end). Supporters 10a supporting heating elements 11 are disposed in the same interval, and such interval may correspond to the length of a pixel in an OLED. According to the current exemplary embodiment of the present invention, the width of heating element 11 is approximately 10 μm, the width of supporters 10a crossing heating element 11 is approximately 5 μm, and the interval between supporters 10a is approximately 100 μm. Supporters 10a having a narrower width of approximately 50 μm are formed across heating element 11, and reinforcers 10b whose diameter is approximately 20 μm are formed on both ends of supporters 10a. Such supporters 10a having reinforcers 10b may reduce loss of heat generated by heating element 11 and maintain mechanical strength.

Accordingly, the heat from heating element 11 is partially absorbed by supporters 10a, however, mostly used to evaporate organic layers, and thus effectively transfer the organic layers.

Regarding transfer of an organic layer by a heating element in a predetermined pattern by using the method of the present invention, the transfer may be performed while the organic layer on the heating element contacts a substrate as described above, or while the organic layer is spaced apart from the substrate. In the latter case, if a gap between the organic layer and the substrate is too wide, a diffused organic layer is formed on the substrate as the evaporated organic layer diffuses in the gap. In order to form the organic layer in a desired pattern on the substrate, the gap between the organic layer and the substrate, which is an evaporation distance of the organic layer, should be properly adjusted. Such gap adjustment may be obtained via suitable design adjustment and ordinary trial and error.

Meanwhile, a substrate used in the example of embodiments is a substrate of an OLED, and thus may include a pixel driving circuit unit of the OLED. Accordingly, organic layers may be transferred to the pixel driving circuit unit.

Each functional layer of an OLED may be any component of a general OLED, such as an emission layer, an electron injection layer on one side of an emission layer, an electron transport layer, a hoe injection layer on another side of an emission layer, or a hole transport layer.

According to such example of embodiments, a transference pattern of an organic layer, which is transferred by a heating element to a substrate, is determined based on a certain pattern of the heating element without using a donor film used in a conventional thermal transfer method. Accordingly, an organic electro luminescence device having high resolution can be obtained by proper designing the heating element, and an organic electro luminescence device having large area can be obtained by optimally designing the heating element. Each functional layer may be formed of a well-known material, and examples of a material of each functional layer are as follows.

The hole injection layer may be formed of a well-known hole injection material, such as a phthalocyanine compound like copper phthalocyanine, a starbust type amine derivative like TCTA, m-MTDATA, m-MTDAPB, and MoO3, a soluble conductive polymer like Pani/DBSA (polyaniline/dodecylbenzenesulfonic acid) or PEDOT/PSS (poly(3,4-ethylenedioxythiophene)/poly(4-styrenesulfonate)), and Pani/CSA (polyaniline/camphor sulfonic acid) or PANI/PSS (polyaniline)/poly(4-styrenesulfonate).

The thickness of the hole injection layer may be approximately between from 100 Å to 10000 Å, and preferably between from 100 Å to 1000 Å. When the thickness of the hole injection layer may be below 100 Å, hole injection characteristics may deteriorate, and when the thickness of the hole injection layer may be above 10000 Å, a driving voltage may increase.

The hole transport layer may be formed of a well-known hole transport material, such as a carbazole derivative like N-phenylcarbazole or polyvinylcarbazole, or a conventional amine derivative having an aromatic fused ring like N,N′-bis(3-methylphenyl)-N,N′-dephenyl-[1,1-biphenyl]-4,4′-diamine (TPD), or N,N′-di (naphthanline-1-il)-N,N′-diphenyl benzidine (α-NPD).

The thickness of the hole transport layer is approximately between from 50 Å to 1000 Å, preferably between from 100 Å to 600 Å. When the thickness of the hole transport layer is below 50 Å, hole transport characteristics may deteriorate, and when the thickness of the hole transport layer is above 1000 Å, a driving voltage may increase.

The electron transport layer safely transports an electron injected from a cathode. The electron transport layer is formed of a well-known material such as an oxazole compound, an isooxazole compound, a triazolic compound, an isothiazole compound, an oxadiazole compound, a thiadiazole compound, a perylene compound, an aluminum complex like Alq3(tris(8-quinolinolato)-aluminium), BAlq, SAlq, Almq3, and a gallium complex like Gaq′2OPiv, Gaq′2OAc, 2(Gaq′2)).

A material of the electron injection layer is not specifically limited as long as the material enables injection of an electron from a cathode. The electron injection layer may be formed of a well-known material such as hybrid of LiF, NaCl, CsF, Li2O, BaO, BaF₂, CSCO₃, and BCP. Also, a depositing condition of the electron injection layer bases on a compound, but selected from a condition range almost equal to that of the hole injection layer.

A phosphorescence dopant included in OPCL or HIL that operates as a green PL emission layer is not specifically limited. [Coumarin 6] or Ir(PPy)3(PPy=2-phenylpyridine) may be used as a green dopant and [4-(dicyanomethylene)-2-t-butyl-6-(1,1,7,7-tetramethyljulolidyl-9-enyl)-4H-pyran (4-(dicyanomethylene)-2-t-butyl-6-(1,1,7,7-tetramethyljulolidyl-9-enyl)-4H-pyran; DCJTB)], PtOEP, RD 61 and RD15 manufactured by UDC, and TER021 manufactured by Merck may be used as a red dopant. Also, other well-known PL materials may be used for green light emission.

A blue dopant used as a blue light emission material of an EL emitter is not specifically limited, and may be DPAVBi, a DPAVBi derivative, distyrylarylene (DSA), a distyrylarylene derivative, distyrylbenzene (DSB), a distyrylbenzene derivative, spiro-DPVBi, and spiro-6P(spiro-sexiphenyl). A red dopant used in a red emission layer is not specifically limited, and may be 4-(dicyanomethylene)-2-t-butyl-6-(1,1,7,7-tetramethyljulolidyl-9-enyl)-4H-piran(4-(dicyanomethylene)-2-t-butyl-6-(1,1,7,7-tetramethyljulolidyl-9-enyl)-4H-pyran; DCJTB), PtOEP, and RD 61 manufactured by UDC. A green dopant used in a green emission layer is not specifically limited, and may be coumarin and Ir(PPy)3(PPy=2-phenylpyridine).

Also, a red phosphor of an EL emitter may be any one of Tris(dibenzoylmethane)phenanthroline europium(III), Bis(2-benzo[b]thiophen-2-yl-pyridine)(acetylacetonate)iridium (III), Tris(1-phenylosoquinoline)iridium(III), Bis(1-phenylisoquinoline)(acetylacetonate) iridium(III), Bis([1-(9,9-dimethyl-9H-fluoren-2-yl)-isoquinoline] (acetylacetonate)iridium(III), Bis[3-(9,9-dimethyl-9H-fluoren-2-yl)-isoquinoline](acetylacetonate)iridium(III), Tris[4,4′-di-tert-butyl-(2,2′)-bipyridine]ruthenium(III) complex, and Tris(2-phenylquinoline)iridium(III).

In addition, a red fluorescent material may be one of 4-(Dicyanomethylene)-2-tert-butyl-6-(1,1,7,7-tetramethyljulolidin-4-yl-vinyl)-4H-pyran, and Tetraphenylnaphthancene, Bis(2-phenylquinoline) (acetylacetonate)iridium (III).

While the example of embodiments have been particularly shown and described with reference to specific example embodiments thereof, it will be understood by those of ordinary skill in the art that various changes in form and details may be made therein without departing from the spirit and scope of the present invention as defined by the following claims.

What is claimed is:

1. A method of fabricating an organic light emitting device (OLED), the method comprising the steps of:
preparing a template having a heating element in a predetermined pattern corresponding to a multilayered structure of the OLED including a plurality of functional layers;
forming an organic layer on the heating element;
drawing a substrate for the OLED close to the heating element of the template; and
transferring the organic layer on the heating element to the substrate by evaporating the organic layer using the heating element.

2. The method of claim 1, in which the forming of the organic layer and transferring of the organic layer are repeatedly performed for forming a multilayered structure having different organic layers on the substrate.

3. The method of claim 1, in which the organic layer is transferred to the substrate while the substrate and the organic layer on the heating element contact each other.

4. The method of claim 2, in which the organic layer is transferred to the substrate while the substrate and the organic layer on the heating element contact each other.

5. The method of claim 1, in which the organic layer is transferred to the substrate while the substrate and the organic layer on the heating element are spaced apart from each other.

6. The method of claim 2, in which the organic layer is transferred to the substrate while the substrate and the organic layer on the heating element are spaced apart from each other.

7. The method of claim 1, further comprising a step of forming the organic layer on the substrate of one of a plurality of OLEDs and forming the organic layer on the substrate of another OLED which is adjacent to the one of the plurality of OLEDs for simultaneously fabricating the plurality of OLEDs, and with the step of the forming of the organic layer and the step of transferring of the organic layer being repeatedly performed for forming a multilayered structure of the plurality of OLEDs.

8. The method of claim 1, in which the step of forming of the organic layer and the step of transferring of the organic layer are repeatedly performed for forming a multilayered structure of a plurality of OLEDs, with a multilayered structure of one of the plurality of OLEDs being completed before a multilayered structure of another OLED which is adjacent to the one of the plurality of OLEDs is formed.

9. The method of claim 1, in which the organic layer is one of plural materials forming the plurality of functional layers of the OLED, and
each of the plurality of functional layers is formed by sequentially stacking each of the plural materials.

10. The method of claim 1, in which the step of preparing of the template prepares templates each corresponding to a plurality of OLEDs on the substrate.

11. The method of claim 1, in which the heating element is formed correspondingly to each of a plurality of OLEDs, and is spaced apart from the template.

12. The method of claim 11, in which, a plurality of supporters each supporting the corresponding heating element, are disposed across the heating element.

13. The method of claim 12, with the plurality of supporters being spaced apart from each other.

14. The method of claim 12, with a reinforcer being disposed at each end of the plurality of supporters.
